(19) United States
(12) Patent Application Publication
(10) Pub. No.: US 2013/0095256 A1
(43) Pub. Date: Apr. 18, 2013

(54) IMPACT AND EROSION RESISTANT THERMAL AND ENVIRONMENTAL BARRIER COATINGS

(71) Applicants: Derek Hass, Charlottesville, VA (US); Balvinder Gogia, Charlottesville, VA (US)

(72) Inventors: Derek Hass, Charlottesville, VA (US); Balvinder Gogia, Charlottesville, VA (US)

(21) Appl. No.: 13/654,142

(22) Filed: Oct. 17, 2012

Related U.S. Application Data
(60) Provisional application No. 61/548,006, filed on Oct. 17, 2011.

(51) Int. Cl. C23C 16/50; C23C 16/48

(52) U.S. Cl. 427/578; 427/248.1; 427/596

(57) ABSTRACT

The present invention provides a process for the application of high temperature coating that provide enhanced impact resistance and erosion damage for the coatings. For high temperature coating systems that provide environmental protection to silicon based ceramics, the process provides the deposition of a silicon-based bond coat on the substrate using the directed vapor deposition with plasma activation and at least one supersonic gas jet nozzle. The process provides the deposition of an EBC layer using the directed vapor deposition with the gas jet nozzle. In one embodiment, the thermal barrier layer may also contain one or more dense embedded layers which further promote impact resistance. Within the process, the particular layers, silicon bond coat, EBC layer and/or TBC layer may be deposited together or specific novel layers applied in combination with other layers deposited using prior known deposition techniques.

### RELATED APPLICATION

The present application relates to and claims priority to Provisional Patent Application Ser. No. 61/548,006 entitled “IMPACT AND EROSION RESISTANT THERMAL AND ENVIRONMENTAL BARRIER COATINGS” having a priority date of Oct. 17, 2011.

### GOVERNMENT SUPPORT

Work described herein was supported by the U.S. Navy under contract N6833510C0231, Phase I SBIR and the Army under contract W911QX-08-C-0040. The United States government has certain rights in the invention.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### FIELD OF THE INVENTION

The present invention relates generally to the field of designing and applying protective coatings onto substrates.

### BACKGROUND OF THE INVENTION

Impact and Erosion Resistance of Ceramic Coatings:

Environmental barrier coatings (EBC) and thermal barrier coating (TBC) systems are protective coating systems used on gas turbine engine components to protect silicon based ceramics and nickel based superalloys, respectively. These coating systems contain combinations of porous and dense ceramic layers and thus, the erosion/impact response of the multiple coating layers is of importance for the overall durability of the coating systems. This is especially the case when gas turbine engines are operated in sandy environments where erosion and impact damage from sand ingestion can be significant, especially on rotating parts. In this case, sand erosion arises when particles entrained in the engine deviate away from gas streamlines due to inertial forces. The erosion rates of the ceramic layers are generally related to the properties of the material (primarily its toughness, elastic modulus and yield strength), however, the microstructure of the coatings also plays a key role. For example, electron beam physical vapor deposited (EB-PVD) yttria stabilized zirconia (YSZ) coatings are reported to have a 10× improvement in erosion resistance over air plasma sprayed (APS) YSZ coatings due to the different response of the columnar microstructure observed in EB-PVD and the splat boundary microstructure of APS.

There exists a need to improve the erosion/impact resistance of current thermal and environmental barrier coating systems. High rate processing approaches which enable thick coatings to be deposited at low cost are also required, especially those which can deposit layers onto complex components having non line-of-sight regions (NLOS).

Environmental Barrier Coatings

Silicon-based ceramic materials (both monolithic and composites) are the leading candidates to replace nickel-based turbine components in next generation gas turbine engines and for use in high temperature structural applications such as heat exchangers. This is primarily due to their high melting points, relatively low density, high toughness relative to other ceramic materials and excellent oxidation resistance in clean oxidizing environments due to the formation of a protective, slow-growing silica scale. However, exposures of these materials to the high temperatures, pressures and velocities of water vapor containing combustion environments alter the effectiveness of the silica scale. Such conditions result in the formation of hydrated silica species (Si(OH)ₓ) and volatilization of the protective scale. This results in decreased oxidation protection and rapid ceramic recession during service. As a result, the environmental durability of these materials is not currently adequate for engine environments. One approach to limit this drawback is through the incorporation of environmental barrier coatings (EBCs) that protect the substrate from environmental attack.

EBCs are coating systems that are applied to the surface of Si-based ceramics resulting in protection against moisture-assisted oxidation-induced ceramic recession. These coatings require many attributes to be successful including; good stability in the presence of water vapor, a mechanism for limiting the transport of oxygen and water vapor to the ceramic substrate, good chemical compatibility at the interface of unlike materials, high temperature phase stability to limit volume changes resulting from phase transformations in the coating materials and the ability to provide thermal and erosion protection.

Current EBC systems use of three layer coating system consisting of an initial silicon layer to provide improved bonding of the mullite to the component, a mullite or mixed mullite and barium strontium aluminosilicate (BSAS) layer and a BSAS top layer, FIG. 1. The BSAS containing layers were more resistant to cracking than earlier systems due to a good CTE match with SiC (when the celsian phase is present). Engine testing indicated a ^{˜}3× lifetime improvement over uncoated components and the system also offers good thermal protection due to the low thermal conductivity of BSAS (1.6 W/m-K).

FIG. 1 provides a schematic illustration of the prior art coating including a silicon bond layer, a mixed mullite and BSAS layer and a BSAS layer. The BSAS layer of FIG. 1 seeks to provide both thermal and environmental protection. FIG. 1B is another illustration with an EBC layer having a thermal and erosion layer on top.

The success of prior EBC work has indicated the feasibility of incorporating ceramic components into current and future engine designs; however, several key coating challenges remain including higher temperature capability and prime reliance (in the presence of impact/erosion/corrosion conditions). Perhaps the most critical issue is the prime reliant aspect of EBC performance, as this requirement fundamentally alters the design aspect of the high temperature coatings currently used on nickel-based superalloy substrates (i.e. thermal barrier coatings). In the case of the TBC's, the coating provides a thermal insulation function which reduces the operation temperature of the component to increase component life. However, due the unreliability in the coating lifetime, the design life of the component is based on the uncoated component lifetime and no (or little) thermal protection benefit is taken to improve engine performance. As a result, local spallation or thinning of the TBC coating is acceptable and accounted for in component design. For the case of EBC coatings, the above design concept is not feasible. At temperatures above 1100° C. in a combustion environment, the SiC—SiC components cannot tolerate even local spallation of the EBC layer without damage to the underlying component as the water vapor can locally attack the protective silica scale which thermally grows on the SiC surface. As a result, successful EBC systems will be required to be prime reliant. This requirement indicates that not only is protection against ceramic recession in a moisture environment provided, but that is it retained in the presence of particle impact, erosion and corrosion (molten sand, CMAS). Despite their demonstrated success, current state-of-the-art EBC systems (silicon bond coat/mixed mullite+BSAS layer/BSAS top layer), have also been shown to be highly susceptible to foreign object damage (FOD) and erosion attack. As a result, advanced EBC systems are sought which both retain or improve the environmental protection afforded and also significantly improve the FOD and erosion resistance.

Thermal Barrier Coating Systems:

Thermal barrier coating (TBC) systems have become widely used to increase the temperature capability of nickel based superalloys used in gas turbine engines and may also provide benefits for diesel engines. A TBC works by creating a thermally insulating layer between the hot engine gases and the air-cooled component. The resulting temperature drop across the coating (170° C. or greater is possible) “protects” the component surface by lowering the temperature that it is exposed to. A lack of durability in these systems, however, has limited engine designers to use them only for component life extension. Experience with TBC's on aircraft engine turbine airfoils has shown that current TBC systems provide a component life improvement of at least 2× and that some modest reduction in component cooling airflow can be achieved. Both contribute to a performance gain for the engines that use them. As TBC technology has matured, increased emphasis is being placed up on the ultimate temperature benefit and durability that can be derived from these systems. Much greater engine performance benefit, up to several percent thrust improvement or specific fuel consumption reduction, is possible if the full potential of a TBC system were realized. Such improvements can only be exploited if the coatings are so reliable that they can be guaranteed not to cause engine failure.

A TBC works by creating a thermally insulating layer between the hot engine gases and the air-cooled component. The resulting temperature drop across the coating (170° C. or greater is possible) “protects” the component surface by lowering the temperature that it is exposed to. Today's TBC systems consist of a bond coat, a thermally grown oxide (TGO), and a thermally insulating ceramic (top coat). In most applications, the bond coat is either a MCrAlY (where M=Ni or NiCo) or a Pt modified aluminide coating. The bond coat (typically ^{˜}50 um thick) is required to provide protection to the superalloy substrate from oxidation and hot corrosion attack and to form an adherent TGO on its surface. The TGO is formed by oxidation of the aluminum that is contained in the bond coat to form aluminum oxide. The thermal barrier layer is most often 7 wt % yttria stabilized zirconia (7YSZ) with a typical thickness of 100-1000 um. The electron beam-physical vapor deposition (EB-PVD) process sometimes used to apply the top coat produces a columnar microstructure with several levels of porosity. The porosity between the columns is critical to providing strain tolerance (via a very low in-plane modulus), as the coating would otherwise spall on thermal cycling due to its thermal expansion mismatch with the superalloy substrate. Finer porosity also exists that aids in reducing the thermal conductivity. Air plasma spray (APS) is a more cost effective option for coating thick thermal barriers onto IGT blades and yields more thermally resistant pore structure. This pore structure, however, has poorer in-plane compliance and thus, these coatings are generally less durable than EB-PVD coatings having a strain tolerant columnar microstructure. The current life-limiting feature of TBCs is delamination of the ceramic topcoat. As the TGO thickness exceeds several microns, it cracks laterally and the topcoat becomes detached, resulting in the failure of the TBC. As the TGO growth rate is a function of temperature, the thermal protection provided by the ceramic top coat during service is also critical for durability. Impact and erosion damage of the top coat which can thin or locally remove sections of the coating can therefore exasperate coating failure mechanism and reduce coating lifetime. As a result, impact and erosion resistant top coats are a critical component of the development of durable TBC systems

### SUMMARY OF THE INVENTION

The present invention provides a process for the application of high temperature coating systems, which not only provide environmental and/or thermal protection to a substrate but are also more resistant to impact and erosion damage for particles which may collide with the coated substrate during service. For high temperature coating systems that provide environmental protection to silicon based ceramics, the process provides the deposition of a silicon-based bond coat on the substrate using the directed vapor deposition with plasma activation and at least one supersonic gas jet nozzle. The process provides the deposition of an EBC layer using the directed vapor deposition with the gas jet nozzle. The process provides the deposition of a TBC layer using the directed vapor deposition with the gas jet nozzle. The deposited layers providing enhanced impact and erosion protection for the deposited layers. In one embodiment, the thermal barrier layer may also contain one or more dense embedded layers which further promote impact resistance. For coating systems which provide thermal protection to nickel based superalloys, the thermal barrier layer may be deposited onto nickel superalloy having an oxidation resistant bond coat. Within the process, the particular layers, silicon bond coat, EBC layer and/or TBC layer may be deposited together or specific novel layers applied in combination with other layers deposited using prior known deposition techniques.

Particular coating architectures, microstructures and compositions are of interest for providing impact and erosion resistance to thermal and environmental protection coatings along with a process to deposit coating onto substrates using a vapor deposition process. The advanced coating systems developed have increased toughness to enable resistance to damage from particle impacts during service.

Coating processing conditions for coating are described that enable the use of a vapor deposition approach to improve the toughness of EBC and TBC coating systems, use of plasma activation to enhance the density of silicon bond coats and ceramic top coats to enhance their impact and erosion resistance, use of ceramic or metallic interlayers to deflect cracks away from the substrate/coating interface and thus limit damage from impact events, use of layers with zig-zag shaped columnar pores to promote impact resistance, use of fine-scaled (^{˜}1 micron) alternating layers to provide additional toughness to EBC layers.

Coating processing conditions for coating are described that further enable placement of alternating layers within the TBC or EBC coating architecture to promote impact resistance, using a combination of toughening approaches to promote erosion and impact resistance in TBC and EBC systems, deposition of tough erosion/impact resistant thermal barrier coating top coats, deposition of coatings with the desired microstructure (i.e. reduced column diameter) for enhanced erosion resistance and multi-source evaporation approach for the deposition of advanced TBC/EBC coating architectures.

Coating processing conditions for coating are further described that enable the use of an Ar carrier gas and a chamber pressure of 10 Pa to obtain fine columns diameters (^{˜}1 to 2 microns) of interest for erosion resistant TBC top coats, optimized process conditions leading to the creation of TBC top coats with significantly better erosion resistance than baseline 7YSZ EB-PVD coatings, systematic improvement in the erosion resistance with a reduction in the column diameter, ambient temperature erosion/impact testing (Domain II/III conditions) leading to a lower material removal rates for DVD deposited 7YSZ coatings in comparison to baseline EB-PVD 7YSZ coatings, high temperature impact testing showed that multi-layered and zig-zag coating architectures achieved excellent impact resistance at high kinetic energy (400 m/s, 1.31 J). Up to a 10.5× improvement in impact resistance was achieved when compared with baseline EB-PVD deposited coatings and the best performing coating for high temperature impact testing was a multi-layer structure where metallic intermediate layers were employed to absorb the impact energy leading to a minimal coating spallation.

This application also defines a particular process condition and/or combinations of various process conditions which may be used for the deposition of erosion and impact resistant coatings in hard to reach regions (Non Line of Sight) of complex components.

### BRIEF DESCRIPTION OF THE DRAWINGS

FIG. 1 is a prior art illustration of A) Schematic illustration of a state-of-the-art T/EBC coating system consisting of a Si bond layer, a mixed mullite+BSAS layer and a BSAS layer.

FIG. 2 illustrates advanced impact/erosion resistant concepts for incorporation into T/EBC coating systems.

FIG. 3 illustrates schematic illustrations showing the projected T/EBC coating systems for impact testing.

FIG. 4 illustrates digital image showing the microstructure of a TBC coating with layers containing different pore morphologies.

FIG. 5 illustrates schematic illustration of a multilayered TBC coat having dense, tough layers incorporated into the top coat structure.

FIG. 6 illustrates schematic illustration showing the incorporation of a compressable “spring like” zig-zag layer into a multilayered TBC architecture.

FIG. 7 illustrates a comparison of the erosion rate of a 7YSZ TBC material in the bulk form and the deposited form using various processing approaches.

FIG. 8 illustrates A) schematic illustration of the DVD system. Shown is the use of multi-source evaporation to deposited alloy compositions. SEM images of DVD deposited coatings are shown including B) a dense rare earth silicate EBC layer, C) a dense Pt layer embedded into a columnar 7YSZ TBC layer, D) thin, alternating layers and E) zig-zag shaped columnar porosity.

FIG. 9A illustrates an SEM micrographs showing the microstructure of as-deposited DVD T/EBC systems consisting of Gd₂Zr₂O₇/EBC/SiC substrate and FIG. 9B illustrates the same T/EBC system following high steam thermal cycle rig (100 hr; 90% water vapor; 1316° C.) testing.

FIG. 10 illustrates SEM images of the initial iteration of advanced impact resistant EBC coating architecture.

FIG. 11 illustrates SEM images of the initial iteration of advanced impact resistant EBC coating architecture.

FIG. 12 illustrates SEM images of the coating architectures exposed to impact testing.

FIG. 13 illustrates SEM images of the DVD deposited 7YSZ TBC top coats having modified microstructures.

FIG. 14 illustrates SEM cross-sectional images of multi-component composition deposited using the directed vapor deposition approach.

FIG. 15 illustrates SEM Micrograph of multi-component based TBC coating deposited using DVD approach.

FIG. 16 illustrates SEM Micrograph of multi-component based TBC coating deposited using DVD approach.

FIG. 17 illustrates SEM Micrograph of multi-component based TBC coating deposited using DVD approach.

FIG. 18 illustrates SEM images of multilayer structure consisting of multi-component and Ni-42Al layers (ATES-104).

FIG. 19 illustrates SEM images of multilayer zig-zag structure consisting of multi-component and Ni-42Al layers (ATES-105).

FIG. 20 illustrates optical images showing the resulting coating surface damage resulting from the impact of a steel ball onto the substrate at a range of velocities (70 to 300 m/sec.).

FIG. 21 illustrates SEM images showing the resulting T/EBC coating containing a dense imbedded interlayer.

FIG. 22 illustrates a summary of the damage induced in a different T/EBC coating architectures following an impact event.

FIG. 23 illustrates A) SEM images showing a T/EBC coating system (Yb₂Si₂O₇/Yb₂O₃) having multiple dense, embedded inter-layers and B) SEM images showing a fine alternating multilayer coating (7YSZ/SiO₂).

FIG. 24 illustrates impact damage of a multi-layered T/EBC system showing crack propagation within a silicon bond coat.

FIG. 25 illustrates that DVD has the ability to combine focused multi-source evaporation (a) with plasma activation (b) for rapid, efficient deposition of the dense coatings (c).

FIG. 26 illustrates SEM micrographs showing the microstructure of Silicon layers deposited using a plasma activated DVD processing approach.

FIG. 27 illustrates ambient temperature erosion resistance of DVD deposited 7YSZ TBC top coats having modified microstructures. The measured erosion resistance of an EB-PVD deposited 7YSZ baseline is also included.

FIG. 28 illustrates microstructure of multi-component based composition deposited using process condition.

FIG. 29 illustrates a variation of relative erosion resistance as a function of process conditions A to E. Erosion conditions: Ambient Temperature, particle size: 70 μm Al₂O₃.

FIG. 30 illustrates a relative change of the TBC sample weight as a function of the number of 60 seconds exposures to alumina media at high nozzle pressure. The DVD deposited 7YSZ TBC coatings showed a reduced erosion rate over EB-PVD deposited 7YSZ TBC coatings.

FIG. 31 illustrates a variation of HT erosion resistance as a function of process condition for multi-component composition

FIGS. 32A-C illustrate digital images of coatings ATES-103 (multi-component TBC), ATES-104 (multilayer) and ATES-105 (zig-zag) after impact testing at 2100 F for an impact velocity of 400 m/s.

FIG. 33 illustrates impact map for multi-component based TBC coatings having columnar structure (ATES-103), multilayer structure (ATES-104) and zig-zag structure (ATES-105), respectively.

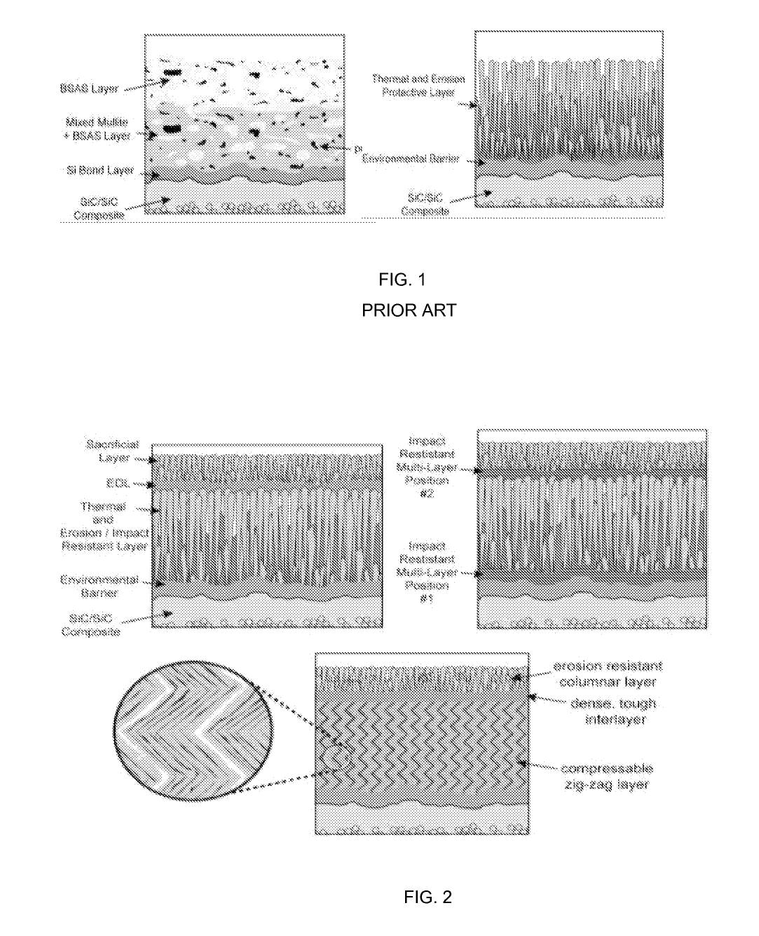

### DESCRIPTION OF THE INVENTION

The use of Physical Vapor Deposition (PVD) and especially gas jet assisted PVD approaches enables the control over pore volume fraction and morphology in the deposited layer. Such approaches have been demonstrated to have the ability to form dense layers, layers with elongated columnar pores of a controllable spacing, layers having fine scaled feathery pores, nanoscaled globular pores and “zig-zag” shaped pores.

Fine scaled multi-layer coatings can be created which can uniquely alter the toughness and thermal conductivity of deposited layers.

Based on the above, it is clear that the use of PVD based processing approaches for T/EBC system deposition enables the ability to incorporate multiple novel concepts into an advanced impact resistant T/EBC system. The use of one or more of these concepts results in a T/EBC coating systems having improved toughness and the ability to absorb and/or deflect the energy imparted by the high velocity impact of a particle onto the coating surface

Vapor Deposited T/EBC system consisting of a columnar TBC layer and a dense EBC layer is one technique. The strain tolerant columnar microstructure of EB-PVD deposited TBC layers acts to limit crack propagation resulting in an order of magnitude improvement in erosion resistance over typical APS deposited microstructures. Further improvements in erosion resistance have been demonstrated using a gas jet assisted PVD approach which yielded fine column diameters. The low defect content of vapor deposited EBC layers is also anticipated to improve the toughness of such layers over APS deposited EBC layers.

High Toughness TBC materials are another technique. The incorporation of high toughness zirconia based TBC materials into advanced T/EBC system can be used to improve to the T/EBC system toughness.

Embedded Dense Layers (EDL) is another technique. The ability to deposit dense EBC layers onto porous, columnar TBC microstructures has been demonstrated to be feasible. Such layers and especially the EBC/TBC interface are anticipated to have a lower toughness than the underlying TBC layer and thus may promote crack propagation along the created interfaces. This would enable cracks resulting from high energy particle impacts to be deflected parallel to the substrate and thus limit the damage induced to the coating to a region above the EDL layer. The result is a T/EBC coating system that would remain intact following one or more impact events.

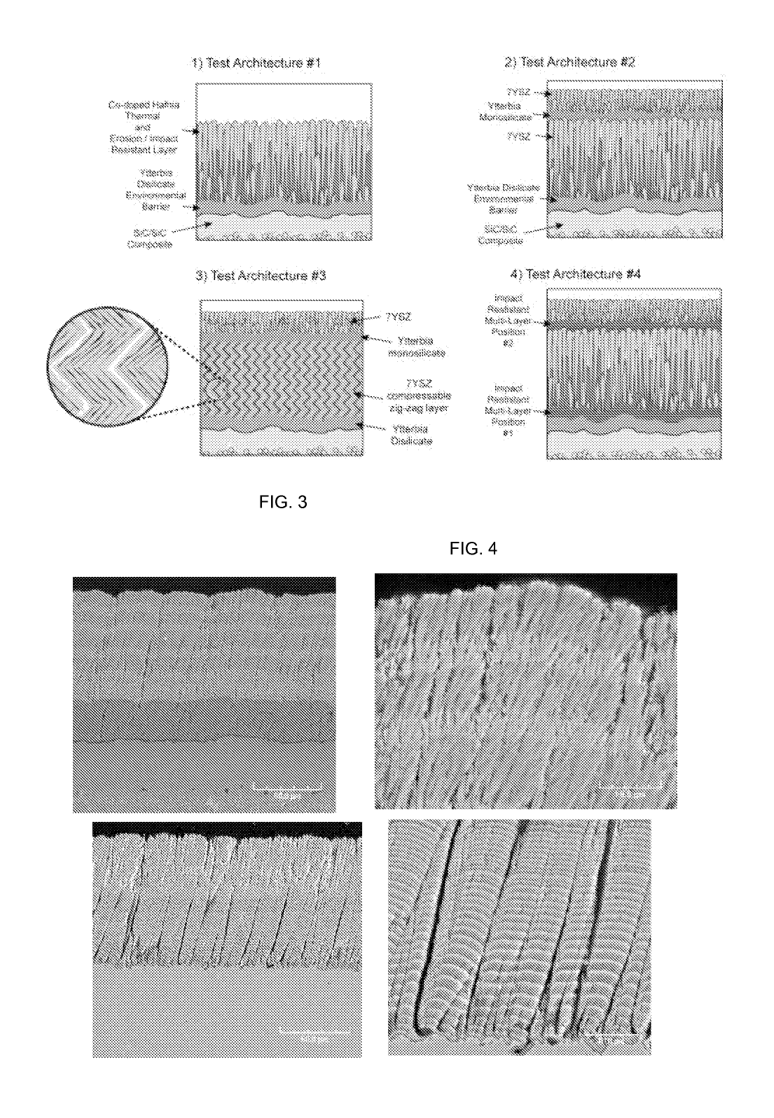

Zig-zag layer incorporation is another technique. Energy absorbing microstructures that absorb some of the energy of an impacting particle should also be effective at increasing the T/EBC toughness. Coating layers having “zig-zag” shaped pores are one approach to obtain this provided a compressible (spring-like) microstructure can be obtained. The further addition of a dense interlayer to distribute the impact load over a wide area of coating may also aid performance. Vapor based processing approaches have demonstrated the effective deposition of “zig-zag” shaped and other “sculpted” columnar pore morphologies. Such a structure is given in FIGS. 2 and 3. FIG. 2A illustrates one example of with impact crack defection layers, including a sacrificial layer. FIG. 2C illustrates an embodiment including a compressible zig-zag layer.

Thin, Alternating multi-layers is another technique. Multi-layer coating concepts consisting of alternating layers of high stiffness materials having a similar elastic modulus and a similar layer thickness can be effective at preventing impact damage to substrates. Coating combinations well suited for higher temperature applications are applicable to the T/EBC systems developed here.

Despite the processing advantages of conventional PVD, such approaches are generally limited for EBC applications. This is due to the low deposition rates (i.e. with sputtering based approaches) which make thick film deposition unfeasible or the poor compositional control of thermal evaporation based PVD processes that results when complex materials having a wide range in vapor pressure between material components (such as is often found for many silicate compositions) are evaporated. The ability to deposit onto complex components having NLOS regions is also of interest. As a result, advanced PVD approaches which retain the key advantages of PVD approaches, but enable enhanced deposition rates, compositional control and NLOS coating are sought to advance current state-of-the-art EBC's.

There are many varying embodiments for deposition. The impact and erosion resistance thermal and environmental barrier coatings allows for varying embodiments of placement of the EBC layer and TBC layer with varying formations of the TBC and/or interlayers disposed therebetween.

A first embodiment type is Vapor Deposited Si Bondcoat plus EBC Layer plus Columnar TBC Top Coat. A second type is Vapor Deposited Si Bondcoat plus an EBC Layer plus a Columnar TBC Layer plus an Interlayer plus a Columnar TBC Outer layer (layers 3 through 5 to be repeated as required). A third embodiment is Vapor Deposited Si Bondcoat plus EBC Layer plus a Zig-zag columnar layer plus Interlayer plus Columnar TBC outer layer. A fourth type is Vapor Deposited Si Bondcoat plus EBC Layer plus Fine Multilayer Impact Resistant Coating (Location #1) plus Columnar TBC Top Coat plus Columnar TBC Layer plus Fine Multilayer Impact Resistant Coating (Location #2) plus Outer Columnar TBC Layer. FIG. 3 illustrates these various embodiments, including a test architecture 1 having a columnar thermal layer. Test architecture 2 is the TBC with an interlayer, in this embodiment being an Ytterbia Monosilicate. Test architecture 3 includes a compressible zig-zag layer and test architecture includes multiple interlayers.

Coating methodologies for achieving wide, comprehensive protection from erosion and impact can be a challenge due to the multiple regimes (erosion damage, compaction and FOD) of particulate damage which can sometimes have conflicting protection requirements and the other requirements for the coating systems (thermal protection, high temperature capability etc.). Nevertheless, recent improvements over the compositional and microstructural control for such coatings create the possibility to achieve significantly enhanced coating architectures in an economical way. By combining novel processing capabilities with the growing understanding of the coating attributes required to limit impact damage new methodologies for erosion protection can be obtained.

One protection technique for the coatings is to control the top coat microstructure-column diameter, column density and intra-columnar pore morphology. Experience with the deposition of TBC top coats using the DVD approach indicates that a wide range of coating microstructures can be obtained depending on the substrate rotation rate, substrate temperature, degree of plasma activation, substrate surface roughness, coating thickness and the chamber pressure. The column diameter, column density and intra-columnar pore morphology are all strongly affected by these parameters and, as a result, alterations to processing conditions were used to optimize the performance of a given material system. Potential opportunities in this area include creating finer columns that limit the volume of material removed if a particle impact results in crack propagation across a column, the removal of feathery pores near the columns tips that may act as crack initiation points and the possibility of forming tougher intra-columnar microstructures.

One improvement of the present impact and erosion resistance layers is the introduction of dense interlayers into the top coat to deflect crack propagation. The incorporation of imbedded dense layers (both metallic and ceramic) into the top coats of thermal barrier coatings can be beneficial for several reasons including i) improved oxidation protection, ii) as a means to reflect radiant heat and iii) as protection against the infiltration of molten salt infiltration (CMAS). By selecting materials such that they are tough, oxidation resistant and have coefficients of thermal expansion that limit thermally induced stresses, tougher structures can also be created having highly tailorable properties. Such layers may additionally add resistance to the erosion mechanisms responsible for material removal in these coatings. They can also promote impact resistance as the interfaces created can deflect cracks so that they propagate parallel to the substrate surface. This allows the impact energy to be consumed without damage to underlying layers of the coating systems.

The introduction of interfaces into the top coats of coating systems can promote impact resistance as the interfaces created can deflect cracks so that they propagate parallel to the substrate surface. This allows the impact energy to be consumed without damage to underlying layers of the coating systems. In addition to the introduction of dense layers into the top coats, other processing techniques can be used to impart interfaces into the coating. This includes the modulation of the chamber pressure and the periodic interruption of the evaporation process. Chamber pressure modulation can create interfaces through the periodic introduction an inert gas to raise the chamber pressure to a level in which the volume fraction and morphology of the coating porosity is altered. The interruption of the evaporation process can, under the right conditions, allow for the re-nucleation of the growing grains and thus, promote the formation of an interface. FIG. 4 illustrates four separate images showing the microstructures of a TBC coating with layers containing different pore morphologies, as varying degrees of magnification.

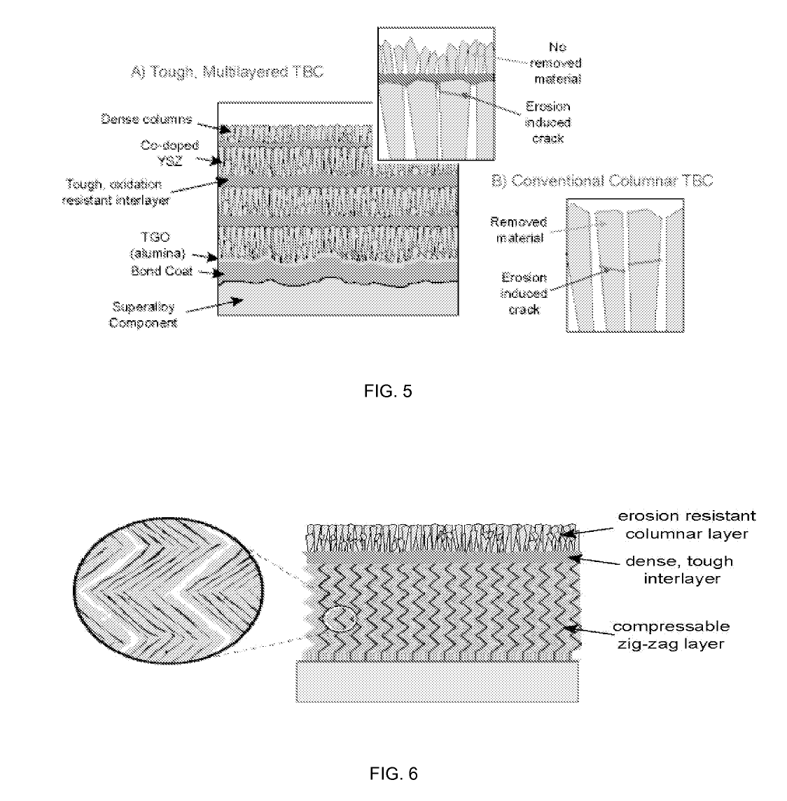

For the case of erosion, the addition of the dense, tough interlayers results in the removal of vertical free surfaces which drive materials removal mechanisms. Cracks which propagate through the diameters of the columns now must also pass through the tough interlayer for material removal to occur, thus significantly increasing the toughness of the “composite” structure, as visible illustrated in FIG. 5. Advanced DVD processing techniques enable not only these interlayers to be created, but also the multiplicity of layers and their thicknesses to be altered. The outermost layer could either be a columnar TBC material or a dense, tough layer.

Another aspect of the present coating technique is energy adsorbing coating architectures. Coating microstructures that adsorb some of the energy of an impacting particle may be of use to limit impact damage (and to a lesser degree erosion damage). One embodiment of such a structure is illustrated in FIG. 6. FIG. 6 is a schematic illustration showing the incorporation of a compressible “spring like” zig-zag layer into a multilayered TBC architecture to create an elastic, energy adsorbing structure with enhanced protection against FOD damage.

The processing method employed to deposit the T/EBC system will also affect the toughness of the resulting layer. In the air plasma spray (APS) process, coatings are created by the repeated impingement of semi-molten particles onto a substrate which results in a semi-dense coating having elongated pores in the plane of the substrate. This porosity, along with the occasional presence of unmelted particles, can result in highly defected coatings having poor mechanical strength. The pores are very effective at impeding the flow of the heat through the coating resulting in coatings with relatively low thermal conductivities, however, the erosion and impact of such layers is typically less than ideal. In using this process for EBC deposition, care must also be taken to limit the formation of metastable amorphous phases which can detrimentally affect coating performance during their transition into the stable crystalline phase. Another issue is frequently the adherence of the APS layers which results primarily from mechanical bonding that is enhanced by high surface roughness. Improved adherence is often desired between the ceramic substrate and APS coatings or between multiple APS layers. Such interfaces are typically the weak links in plasma sprayed EBC systems.

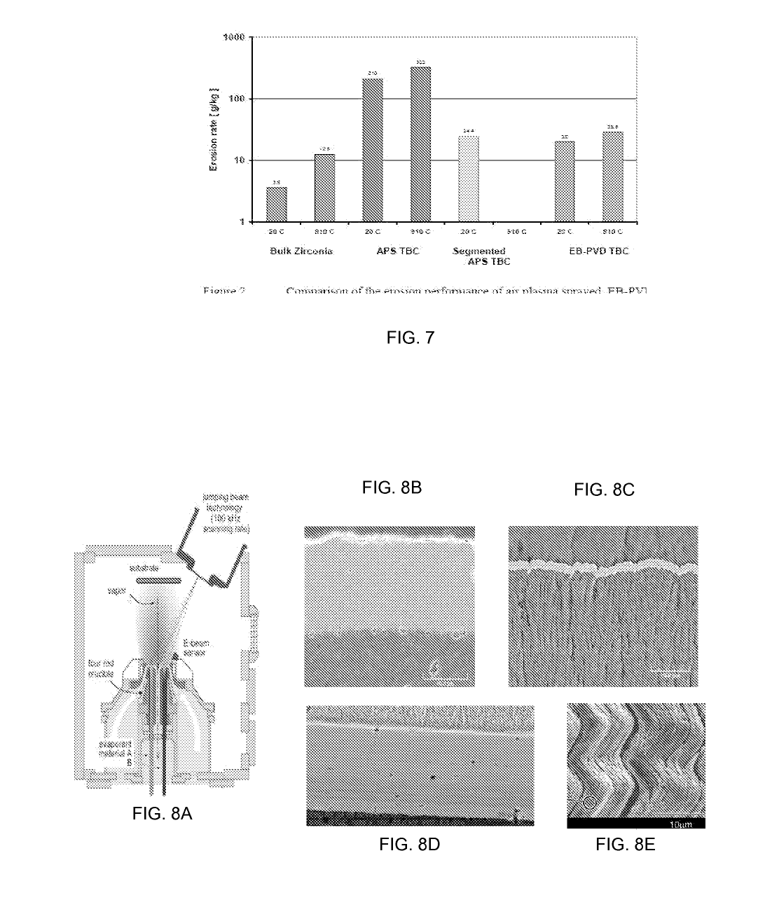

Typically, the impact/erosion resistance of deposited layers of a given coating material is highly dependent on the coating microstructure. For example, electron beam physical vapor deposited (EB-PVD) YSZ coatings are reported to have a 10× improvement in erosion resistance over air plasma sprayed (APS) YSZ coatings due to the different response of the columnar microstructure observed in EB-PVD and the splat boundary microstructure of APS. The total pore volume fraction is also important as the erosion of APS coatings can be improved by aging treatments that reduce pore volume fraction. Refining the column diameter of EB-PVD coatings further improves the erosion rate of EB-PVD coatings with an additional factor of 10 improvement possible with a 5× reduction in the column diameter. Thus, the lowest reported erosion rates of EB-PVD or APS coatings are from fine columned EB-PVD layers. In comparison, fully dense, bulk YSZ yields considerably better erosion resistance than either porosity containing coating, FIG. 7. The architecture of the multiple layered coatings can also be a variable used to modify the erosion/impact performance of the coating system. For example, enhanced EBC coating thickness reduces the impact induced damage of a CMC substrate. The addition of coating layers which absorb impact energy (through a dense, sacrificial layer or compressible coating layers) are additional examples.

Directed vapor deposition (DVD), is an advanced approach for vapor depositing high quality coatings. It provides the technical basis for a flexible, high quality coating process capable of atomistically depositing dense or porous, compositionally controlled coatings onto line-of-sight and NLOS regions of components. Unlike other PVD approaches, DVD is specifically designed to enable the transport of vapor atoms from a source to a substrate to be highly controlled. To achieve this, DVD technology utilizes a supersonic gas jet to direct and transport a thermally evaporated vapor cloud onto a component. Typical operating pressures are in the 1 to 50 Pa range requiring that only fast and inexpensive mechanical pumping need be used resulting in short (few minutes) chamber pump-down times. In this processing regime, collisions between the vapor atoms and the gas jet create a mechanism for controlling vapor transport.

FIG. 8A is a schematic illustration of a DVD system using multi-source evaporation to deposit alloy compositions. FIG. 8B illustrates a dense rare earth silicate EBC layer. FIG. 8C illustrates a dense Pt layer embedded in a columnar 7YSZ TBC layer. FIG. 8D illustrates thin alternating deposit layers and FIG. 8E illustrates zig-zag shaped columnar porosity.

This enables several unique capabilities including high rate deposition. Vapor phase collisions between the gas jet and vapor atoms allow the flux to be “directed” onto a substrate. Since a high fraction of the evaporated flux impacts the substrate (i.e. the materials utilization efficiency is increased) instead of undesired locations (such as the walls of the vacuum chamber) a very high deposition rate (>10 μm min ⁻¹) can be obtained.

For NLOS deposition, gas jet can be used to carry vapor atoms into internal regions of components and then scatter them onto internal surfaces to result in NLOS deposition. In one embodiment, the use of high frequency e-beam scanning (100 kHz) allows multiple source rods to be simultaneously evaporated. By using binary collisions with the gas jet atoms, the vapor fluxes are intermixed allowing the composition of the vapor flux (and thus, the coating) to be uniquely controlled. This allows alloys with precise compositional control to be created even when large vapor pressures difference exist between the alloy components. It also enables multilayered coatings to be deposited in a single run.

Another aspect is coating microstructure control. The ability to deposit dense layers of both ceramics and metals has been demonstrated by the DVD technique. Strain tolerant, columnar microstructures have also been shown. Such columnar layers have unique control over the column diameter, inter-columnar pore width and column morphology (i.e. zig-zag shaped columns have been demonstrated).

The use of multiple source evaporation to create alternating layers of different materials with fine (sub-micron) layer thickness is feasible with DVD.

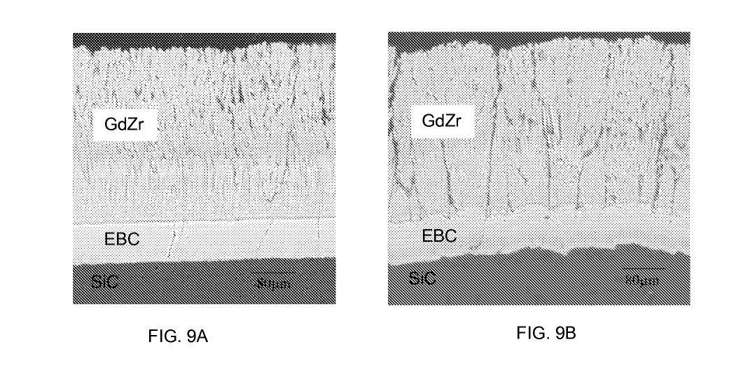

It has also been shown that hollow cathode plasma activation can be used to improve the density of DVD layers if required. This enables a large percentage of all gas and vapor species to be ionized. The ions can then be accelerated towards the coating surface by an applied electrical potential increasing their velocity (and thus the kinetic energy) and thus, allowing the coating density and potentially the coating crystallinity to be increased. These characteristics combine to make DVD both a useful tool for the development of new EBC compositions and as a next generation deposition approach for these coatings. In fact, in prior work, the DVD process has already been demonstrated to enable the creation of rare earth silicate coatings having high density, the desired phase formation and good adhesion to Si based ceramics. FIG. 9A illustrates an SEM micrograph showing the microstructures of as-deposited DVD T/EBC systems consisting of Gd₂Zr₂O₇/EBC/SiC substrate. FIG. 9B illustrates the same T/EBC system following a high stream thermal cycle rig at 100 hours, 90% water vapor and 1316 degrees Celsius testing. The process has also been used to deposit zirconia-based thermal barrier coatings (TBC) at high rates (>80 μm/min.) having strain tolerant columnar microstructures, good durability, low thermal conductivity and enhanced erosion resistance.

Enabling the production of the advanced erosion and impact resistant coatings required to meet the future needs of military engines uses an advanced processing approach. The present invention uses a novel Directed Vapor Deposition (DVD) approach for the deposition of TBC coatings to create microstructure modifications and coating architectures to improve the erosion and impact resistance and to achieve a comprehensive TBC system that provides improved erosion and impact protection, thermal protection, enhanced thermal cycle lifetimes. The DVD process is a modification of EB-PVD that provides an economic methodology for coating airfoils with next-generation TBCs while still meeting the composition and microstructure requirements necessary for acceptable time-on-wing, flight safety and affordability. DVD is based on the incorporation of a supersonic gas jet into a modified electron beam evaporation system. The gas jet focuses the evaporated materials onto a part allowing for high rate, highly efficient processing conditions. These conditions have also been shown to promote non-line-of-sight coating and intermixing of vapor flux from multiple evaporation sources, and therefore may enable the coating of the complex shaped parts with advanced compositions.

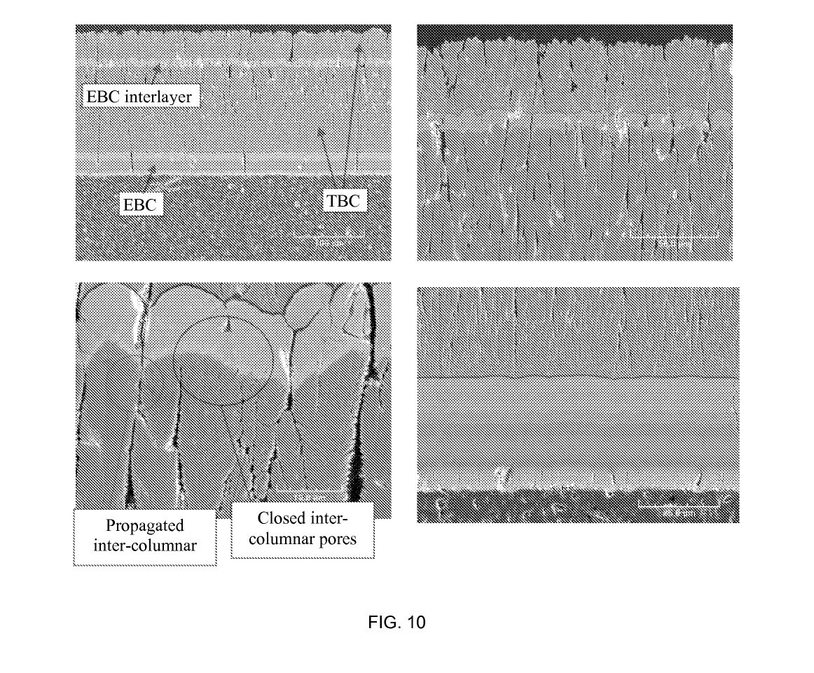

Novel coating synthesis techniques were used to create T/EBC systems containing materials, microstructures and architectures anticipated to promote improved erosion/impact resistance. The results, FIGS. 10-12, indicated the feasibility in creating novel T/EBC systems above using a DVD processing approach.

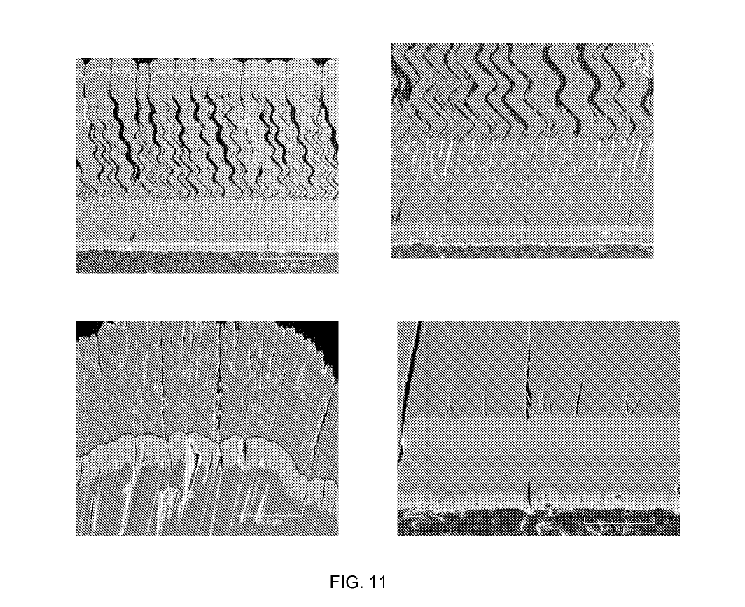

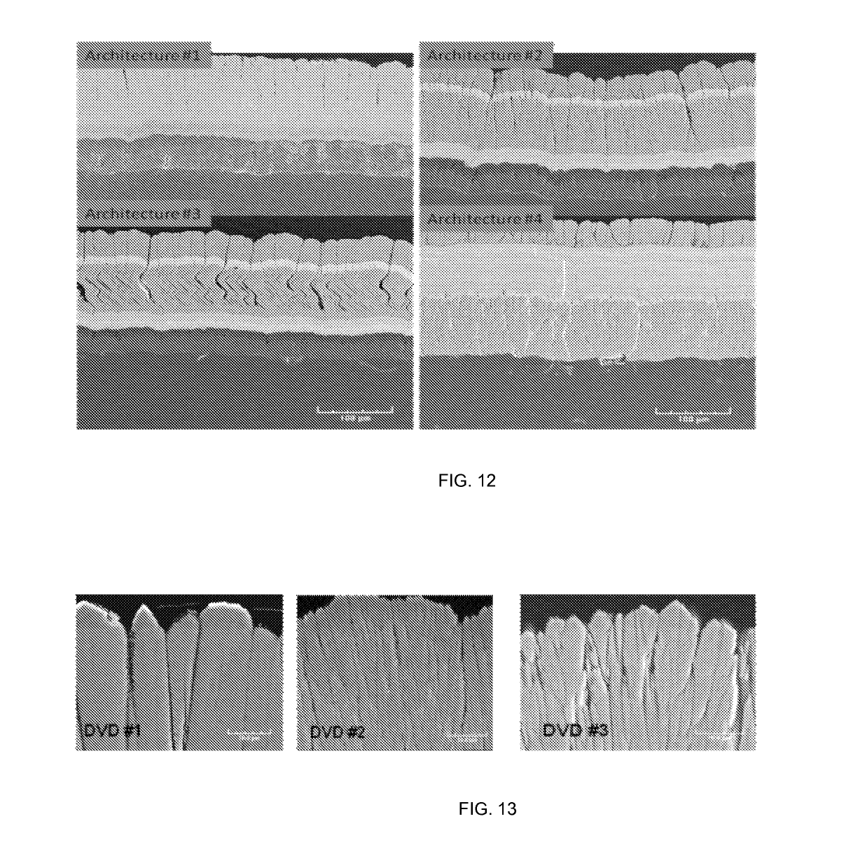

FIG. 10 illustrates SEM images of advanced impact resistant EBC coating architecture, in this embodiment including silicate based EBC layer, a columnar zirconia thermal barrier, a silicate based EBC interlayer and a columnar zirconia thermal barrier. FIG. 11 illustrates SEM images of the initial iterations of advanced impact resistant EBC coating architecture. The coatings in this embodiment include a silicate based EBC layer, a columnar zig-zag zirconia thermal barrier, a silicate based EBC interlayer and a columnar zirconia thermal barrier. FIG. 12 provides SEM images of the coating architectures exposed to impact testing.

Due to the wide vapor pressure difference between many oxide ceramics and silica it has been demonstrated that multiple source co-evaporation will be required to create compositionally controlled silicate materials using thermal evaporation approaches. Multi-source evaporation in DVD is enabled by the use of advanced e-beam gun technology having high speed e-beam scanning (up to 100 kHz) and a small beam spot size (<0.5 mm). This allows multiple crucibles placed in close proximity to one another to be precisely heated and the source material evaporated. The carrier gas surrounds the vapor sources and allows the vapor from the neighboring melt pools to interdiffuse. By altering the electron beam scan pattern to change the temperature (and thus the evaporation rate) of each source material the composition of the deposited layer can then be controlled. In effect this is a splitting of the beam into two or more beams with precisely controllable power densities. As a result, the DVD system enables the evaporation of several materials simultaneously. Process conditions have been identified that lead to very good mixing between the vapor fluxes of the different melt pools leading to a uniform coating composition across the substrate. This intermixing is due to the closely spaced melt pools and vapor phase collisions that allow lateral diffusion of vapor atoms.

The use of multiple source rod evaporation in DVTI's production scale DVD (PS-DVD) coater is given where co-evaporation of two 1″ diameter source rods is shown. The system is equipped with an advanced 60 kW e-beam gun that has a high accelerating voltage (75 kV) to enable the use of elevated chamber pressures (up to 33 Pa), extremely large +/−30° beam deflection angles and very high (>10 KHz) scanning frequencies. These attributes enable evaporation from crucibles placed at most any point on the interior of chamber. To take advantage of this, the crucible/nozzle apparatus allows for the crucible-to-crucible spacing to be easily adjusted. This spacing along with the supersonic gas jet nozzle geometry controls the achievable deposition area, its vapor density and finally the maximum throughput during production scale coating. It is envisioned that the deposition of a multi-component environmental barriers and a microstructurally controlled outer layer of complex compositions could all be applied in a single coating operation. In this work, DVD was used to deposit silicate materials of the desired composition using a co-evaporation approach for use as environmental barrier layers.

Using the previously obtained processing conditions required to obtain the desired silicate, zirconate and silicon compositions, deposition onto pre-heated substrates was performed.

DVD process has been used to deposit 7YSZ and multi-component TBC top coats having modified microstructures. Table 1& 2 summarizes the process conditions for deposition of these top coats which resulted in modifications in microstructures. Top coat microstructures were created by altering the DVD process conditions and using a hollow cathode plasma activation system to create a range of column diameters, column densities and intra-columnar pore morphologies, FIG. 13-17. Substrate were heated up to 1050° C. using a radiant heating. Microstructural analysis was performed to evaluate the effect of process conditions on the columnar structure, diameter, compactness of the coatings. The diameter of the columns could be altered with modification of the DVD processing conditions. The use of an Ar carrier gas and a chamber pressure of 10 Pa resulted in the finest observed columns diameters (^{˜}1 to 2 microns).

TABLE 1
Summary of DVD processing conditions employed for the creation of initial T/EBC coating systems.

| | | | Right | Left | Right | Left | | | |
|---|---|---|---|---|---|---|---|---|---|
| Run | Right | Left | Feed Rate | Feed Rate | Source | Source | Mass | Max | |
| Code | Source | Source | (mm/min) | (mm/min) | Evap. (g) | Evap. (g) | Ratio | Temp. (° C.) | Time |
| IEBC-1 | Yb2O3 - | SiO2 - | 0.625 | 2.43 | 17.63 | 13.61 | 1.3 | 1014 | 15 |
| | ¾″ | ¾″ | | | | | | | |
| IEBC-2 | — | zirconia - | — | 1.6 | — | 55.13 | NA | 1008 | 15 |
| | | A4 - 1″ | | | | | | | |
| IEBC-3 | — | zirconia - | — | 1.5 | — | 96.01 | NA | 1050 | 30 |
| | | A4 - 1″ | | | | | | | |
| IEBC-4 | Yb2O3 - | SiO2 - | 1.25 | 2.43 | 12.88 | 6.48 | 1.98 | 1002 | 3 |
| | ¾″ | ¾″ | | | | | | | |
| IEBC-5 | zirconia - | — | 1.5 | — | 20.42 | — | NA | 1032 | 3 |
| | A4 - 1″ | | | | | | | | |
| IEBC-6 | Si | Si | 0.075 | 0.075 | 5.21 | 4.44 | NA | 770 | 60 |
| IEBC-7 | Yb2O3 - | SiO2 - | 0.625 | 2.43 | 19.56 | 14.30 | 1.37 | 1035 | 15 |
| | ¾″ | ¾″ | | | | | | | |
| IEBC-8 | hafnia | hafnia | 1.5 | 1.5 | 43.77 | 40.46 | NA | 953 | 17 |
| | HC-1 | HC-1 | | | | | | | |
| IEBC-9 | YSZ | YSZ | 1.5 | 1.5 | | | NA | | |
| IEBC-10 | Yb2O3 - | SiO2 - | 1.75 | 2.43 | | | | | 3 |
| | ¾″ | ¾″ | | | | | | | |
| IEBC-11 | hafnia | | | | | | | | |
| | HC-1 | | | | | | | | |

TABLE 2
Summary of Process conditions for
7YSZ (for DVD #1, 2, 3) of FIG. 13.

| Process | Coating | | Chamber | | |
|---|---|---|---|---|---|
| Condition | material | Gas | Pressure (Pa) | RPM | Plasma condition |
| DVD#1 | 7YSZ | He | 9 | 20 | x |
| DVD#2 | 7YSZ | He | 17 | 20 | x |
| DVD#3 | 7YSZ | He | 24 | 20 | 60 A/(+/−)200 V |

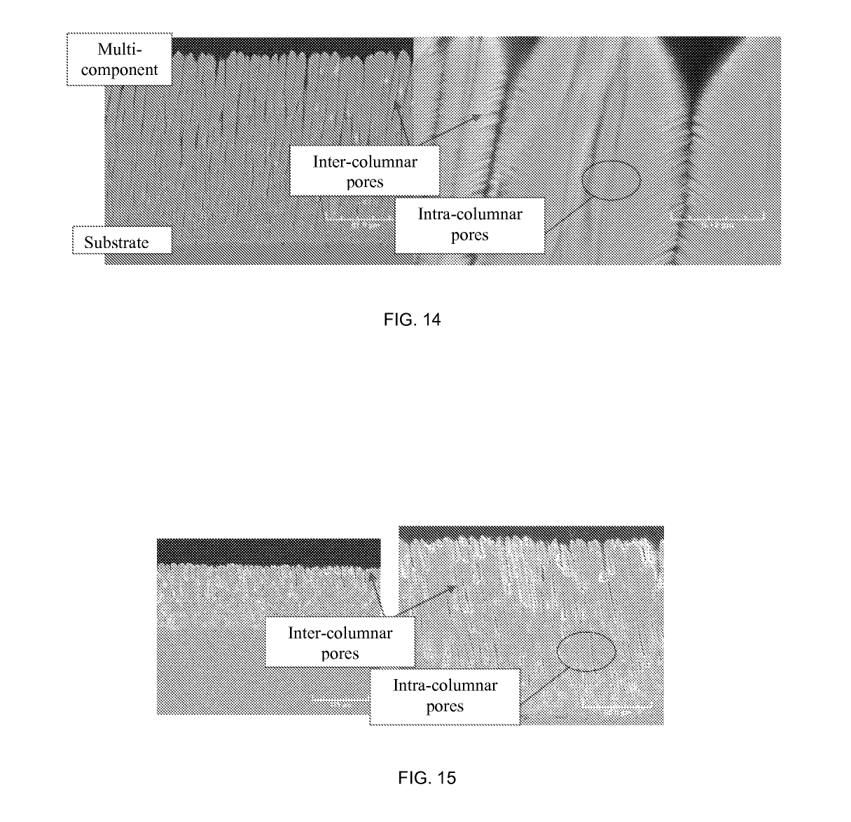

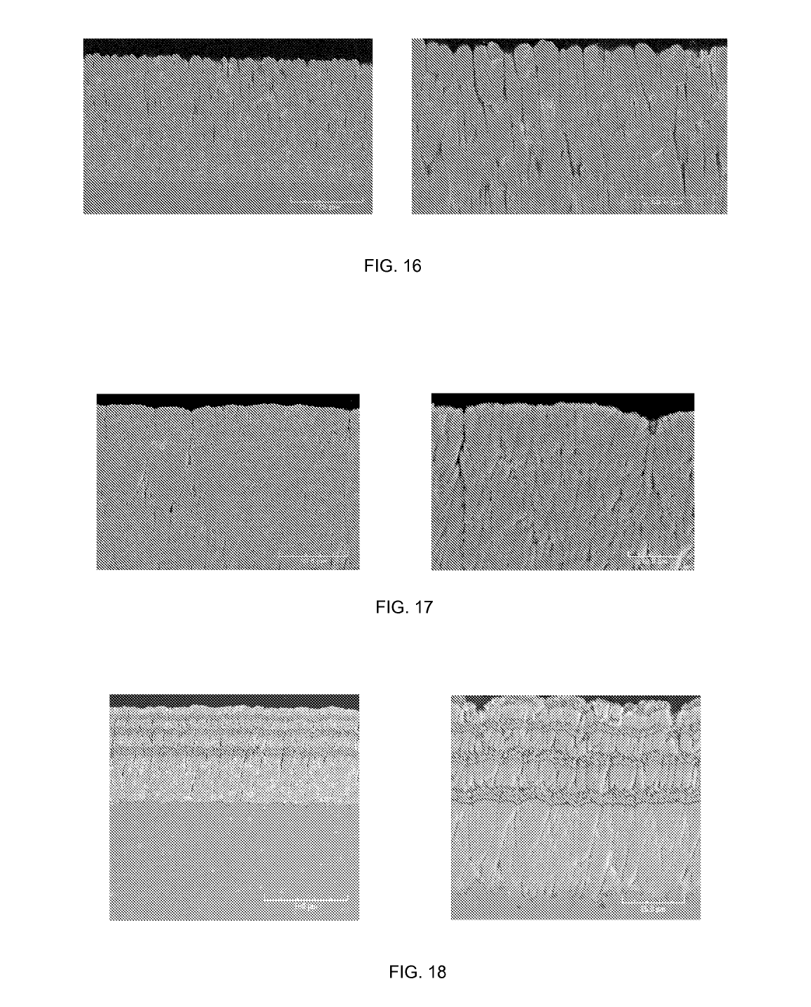

FIG. 14 illustrates an SEM cross-sectional images of multi-component composition deposited using the directed vapor deposition approach. The coating has a strain tolerant columnar microstructure with finer intra-columnar porosity aligned nearly parallel to the heat conduction path. FIG. 15 illustrates an SEM Micrograph of multi-component based TBC coating deposited using DVD approach (Process condition A—ATES-27). FIG. 16 illustrates an SEM Micrograph of multi-component based TBC coating deposited using DVD approach (Process condition B—ATES-28). FIG. 17 illustrates an SEM Micrograph of multi-component based TBC coating deposited using DVD approach (Process condition C—ATES-29).

Coating architectures that can protect against both the erosion mechanisms of smaller impacting particles and the damage created by impact/FOD will be required in actual engine environments.

Therefore, the development of toughened TBC coating architectures is required which would provide multi-functional erosion/impact protection. To achieve this goal, multi-layered and zig-zag coating architectures were created

In one embodiment, advanced coating architectures containing dense, metallic interlayers within the top coat structures were also deposited. Such layers provide additional toughness to the structure since the removal of material would require not just crack propagation through a brittle, ceramic layer containing numerous cracks and defects (as desired for low thermal conductivity), but also through a tough metallic layer. Further, the metallic layer help distribute the load applied by the impacting particle over a broader area to therefore provide an additional mechanism for the coating to handle the applied energy.

Multilayer coatings were deposited following the coating sequence as (1) ceramic-component (7YSZ or multi-component) as the base layer, (2) followed by the metal layer (Pt or Ni-42Al), (3) ceramic-component (7YSZ or multi-component) and then (2) and (3) steps were repeated several times depending upon the no. of required layers.

FIG. 18 shows the SEM image of multilayer coating with alternate layers of 7YSZ (multi-component) and Pt (Ni-42Al) composition.

Another type of coating architecture, specifically tailored for impact resistance, was the incorporation of a compressible, zig-zag microstructure into the TBC. Such structures have been shown to have reduced thermal conductivity and may also provide an additional mechanism for energy absorption. Coating architectures of this type were created by alternatively titling the substrates at an angle of +/−75° with an associated dwell until the required coating thickness was achieved. This was followed by a deposition of metallic layer and columnar structure on the top.

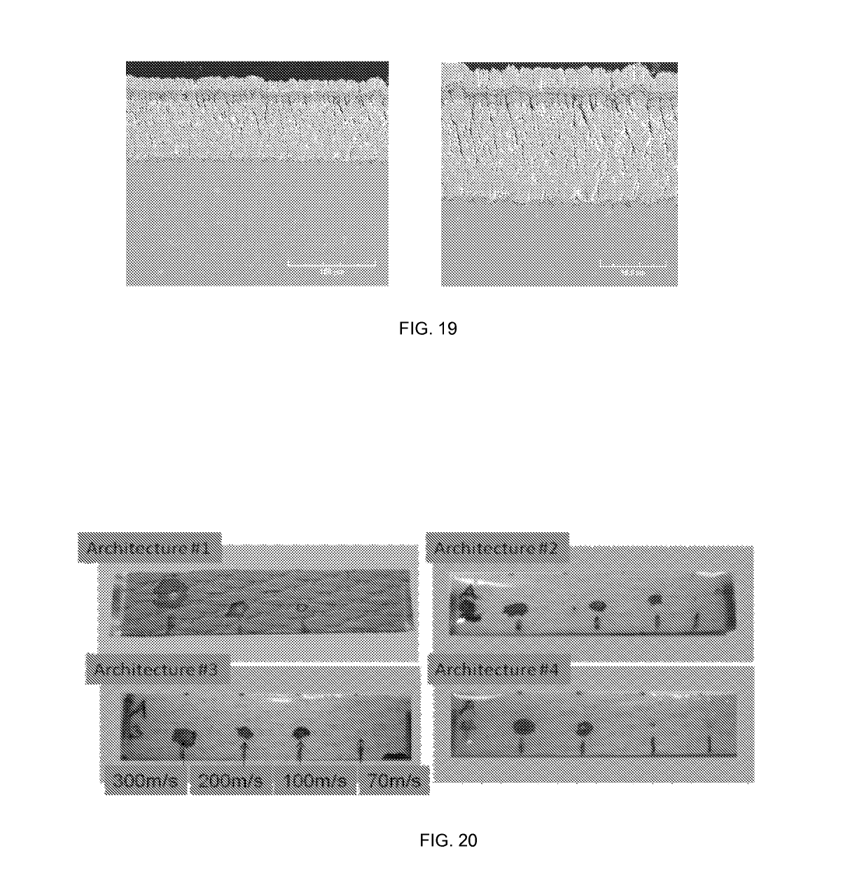

FIG. 19 shows the SEM image of such kind of zig-zag structures (7YSZ and multi-component. respectively) deposited using the multiple source approach. This consists of zig-zag layer of 7YSZ and/or multi-component based composition with intermediate metallic layer of Pt or Ni-42Al followed by columnar structure.

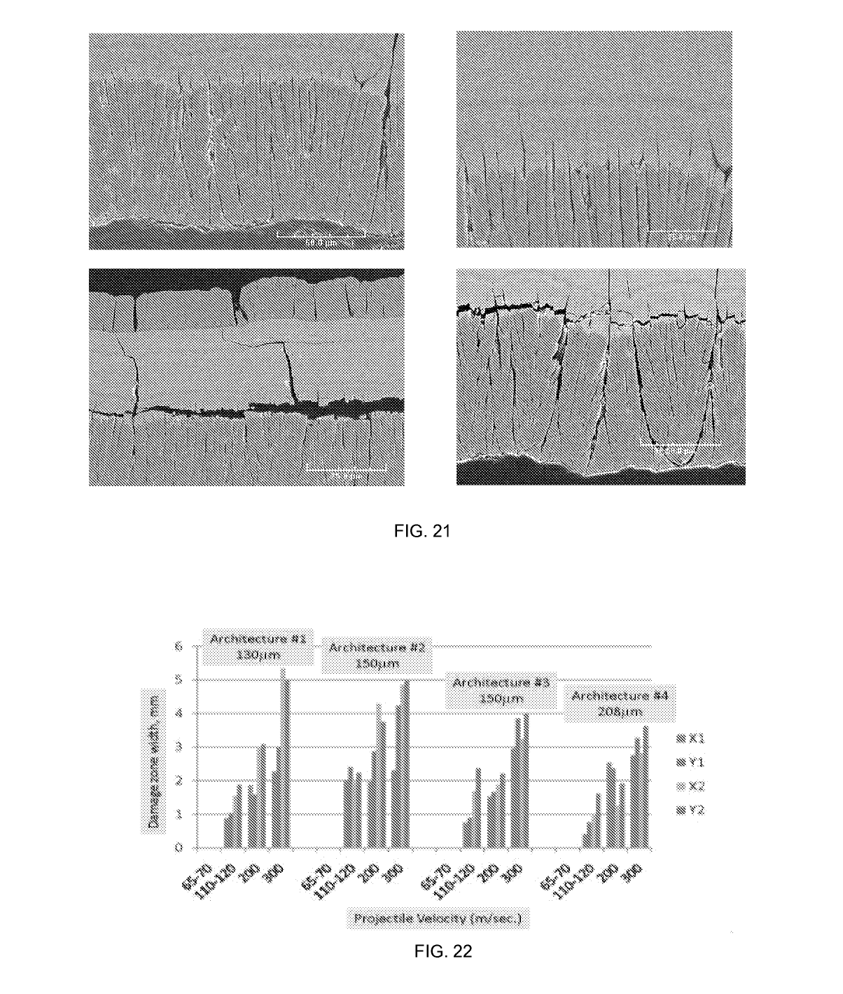

FIG. 20 illustrates on embodiment of Impact testing on the novel coating systems. The results indicated that modification to the T/EBC architecture could be used to alter the damage observed in the T/EBC coating and CMC substrate following impact testing, FIG. 21-22. T/EBC coatings having energy absorbing architectures, such as dense embedded layers and “zig-zag” pore morphologies were observed to limit T/EBC and CMC substrate damage as compared to a baseline PVD deposited T/EBC coating having a standard columnar microstructure. The low toughness of the Si bond coats used in these coatings were also observed as a common failure location of T/EBC coating systems indicating a need to further enhanced the processing conditions used to create such layers.

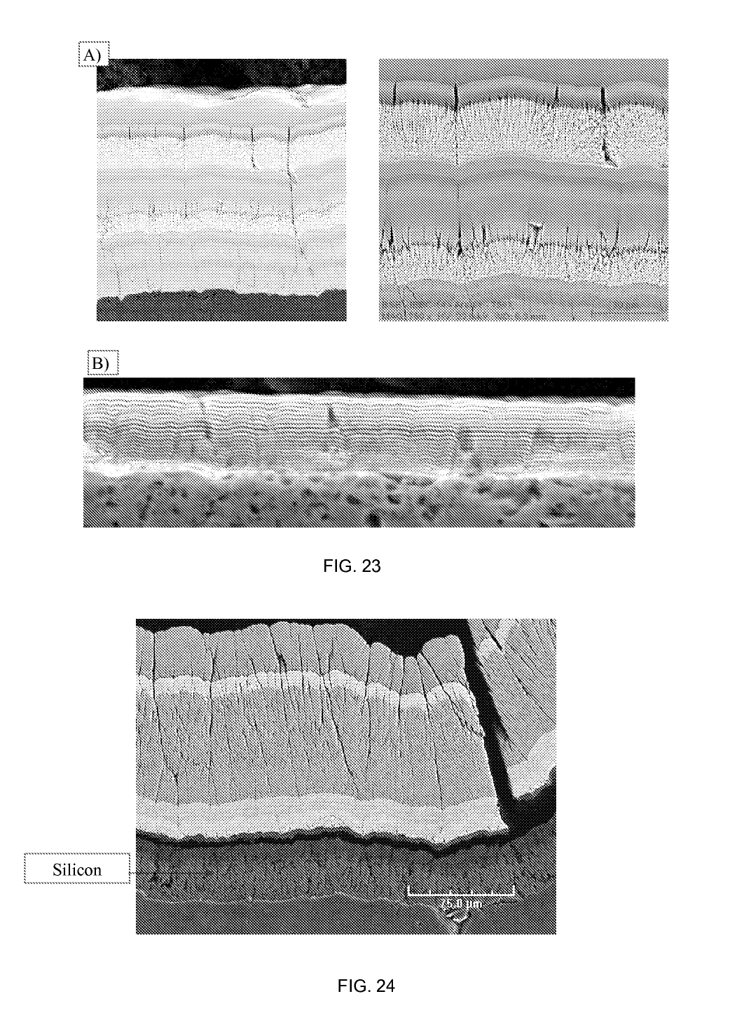

The feasibility of employing further coating enhancements, such as the inclusion of multiple embedded layers into the TBC layer, FIG. 23A, and the use of fine multilayered structures, FIG. 23B, were also demonstrated.

A key observation of early impact testing was the initiation of cracks in the silicon bond coat layers upon impact. This can be related, in some extent, to the low relative toughness of silicon, but is also likely due in part to the lower than theoretical density of the deposited silicon layers, FIG. 24. The most important issue for the vapor deposition of Si is the deposition temperature. This is due not only to its effect on the coating microstructure (i.e. coating density is enhanced by increased deposition temperature) but also its effect on the sticking efficiency of the Si (i.e. the sticking efficiency is observed to dramatically decrease with increasing temperature). The result is that a balance must be struck between the coating density and sticking efficiency (which controls the deposition rate and coating thickness). Currently, deposition temperatures which yield reasonable deposition rates do not result in fully dense coating microstructures. Potential modifications include reducing the chamber pressure to promote coating density or to use plasma activation to ionize the vapor atoms and deposited them with higher energy.

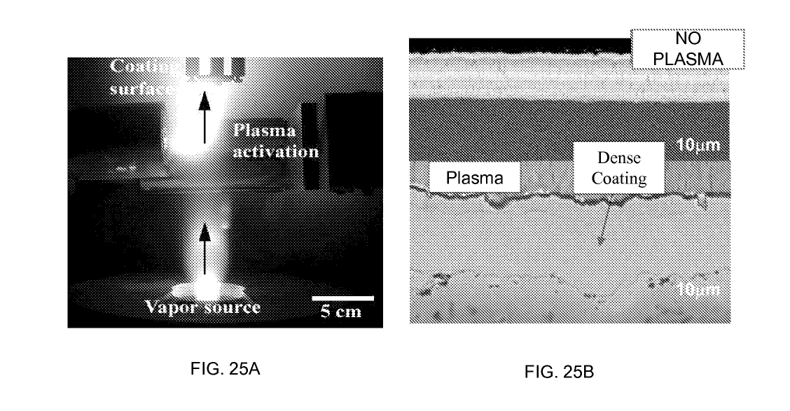

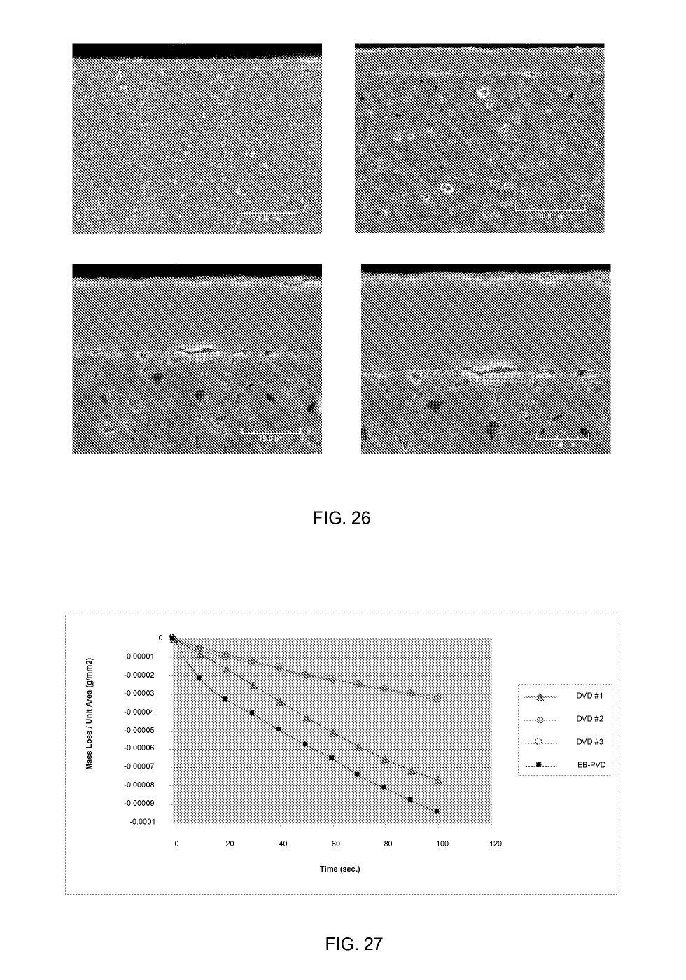

Plasma-activation in DVD is performed by a hollow-cathode plasma unit capable of producing a high-density plasma in the system's gas and vapor stream, FIG. 25A. The particular hollow cathode arc plasma technology used in DVD is able to ionize a large percentage of all gas and vapor species in the mixed stream flowing towards the coating surface. This ionization percentage in a low vacuum environment is unique to the DVD system. The plasma generates ions that can be accelerated towards the coating surface by either a self-bias or by an applied electrical potential. Increasing the velocity (and thus the kinetic energy) of ions by using an applied potential allows the energy of depositing atoms to be varied, affecting the atomic structure of coatings. The effect of using plasma activation on the coating microstructure of a NiAl coatings is shown in FIG. 26B. Both coatings in this case were deposited using a substrate temperature of 750° C. The coating on the right also used plasma activation with a +100V substrate bias. The plasma deposited coating had a greatly densified microstructure. In this task, the use of plasma activation to promote improved Si bond coat microstructure has been explored.

During this work, Si coating runs were performed using plasma activated DVD conditions. To achieve this, SiC substrates (1″×1″) were heated using a back side resistive heater to temperatures in the range of 600 to 700° C. The goal of these runs were to obtain suitable deposition rates (i.e. maintain good sticking coefficients for Si) and a dense coating microstructure. Microstructural images of the as deposited silicon layer are given in FIG. 26. Note that a high density Si layer is obtained. The layer appears from visual observation to be significantly denser than the previously deposited Si layers shown in FIG. 24. A suitable coating thickness of 18 μm was obtained. Based on these results, the use of plasma assisted Si deposition will be incorporated into future T/EBC coatings systems.

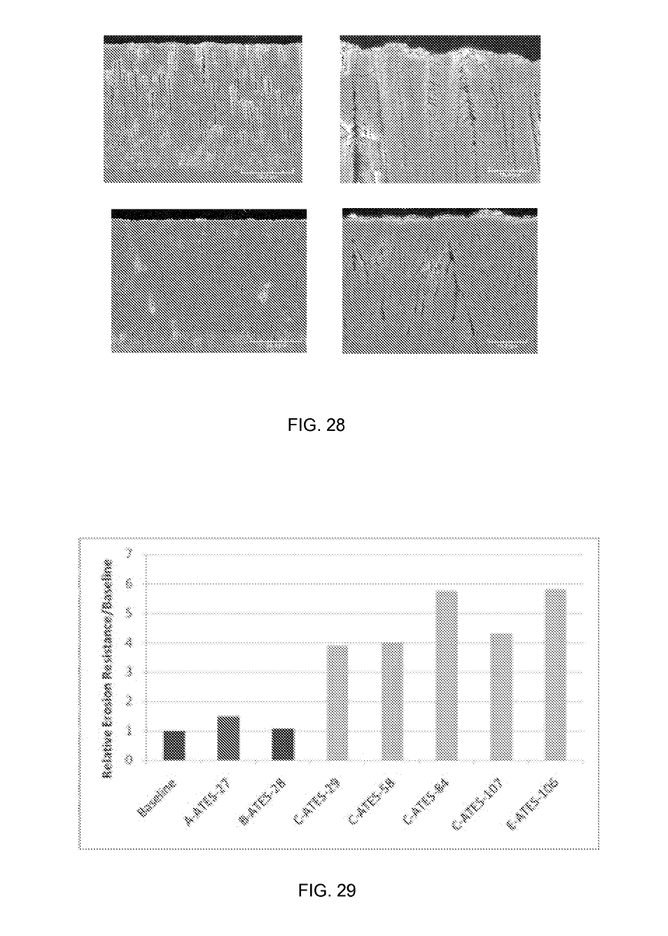

Superalloy coupons coated with all the above mentioned coating architectures were tested for erosion performance. Ambient temperature erosion testing was performed on the DVD deposited coatings and 7YSZ baseline coatings created using EB-PVD. An ambient temperature erosion test was devised in which alumina particles of a given size and energy was projected at coated coupons. The testing set up consisted of an air pressurized nozzle held at set distance from the TBC sample to impinge alumina media onto the sample and a substrate holder with a means to mask the edge of the coupons. Baseline conditions used an air pressure of 28 psi and alumina media having an average particle size of 70 μm. The coatings were exposed to the particle stream for 60 seconds after which the coating was inspected and the weight change of the sample measured. This was optimized for particle energies which result in failure mechanisms indicative of Domain I erosion damage. This setup was used for all room temperature erosion. FIG. 27 shows the ambient temperature erosion resistance of DVD deposited 7YSZ TBC top coats having modified microstructures. The measured erosion resistance of an EB-PVD deposited 7YSZ baseline is also included. FIG. 28 shows the SEM images of multi-component TBC's (deposited under process condition A and C (see Table 2)) following exposure to ambient temperature erosion test. The relative erosion resistance for these coatings is summarized in FIG. 29 providing variation of relative erosion resistance as a function of process conditions A to E. Erosion conditions: Ambient Temperature, particle size: 70 μm Al₂O₃. For comparison purposes the relative resistance ratio for EB-PVD is also included. It is clear that process condition C yields a significantly improved erosion resistance. The experimental data in this case illustrates a systematic improvement in the erosion resistance with a reduction in the column diameter.

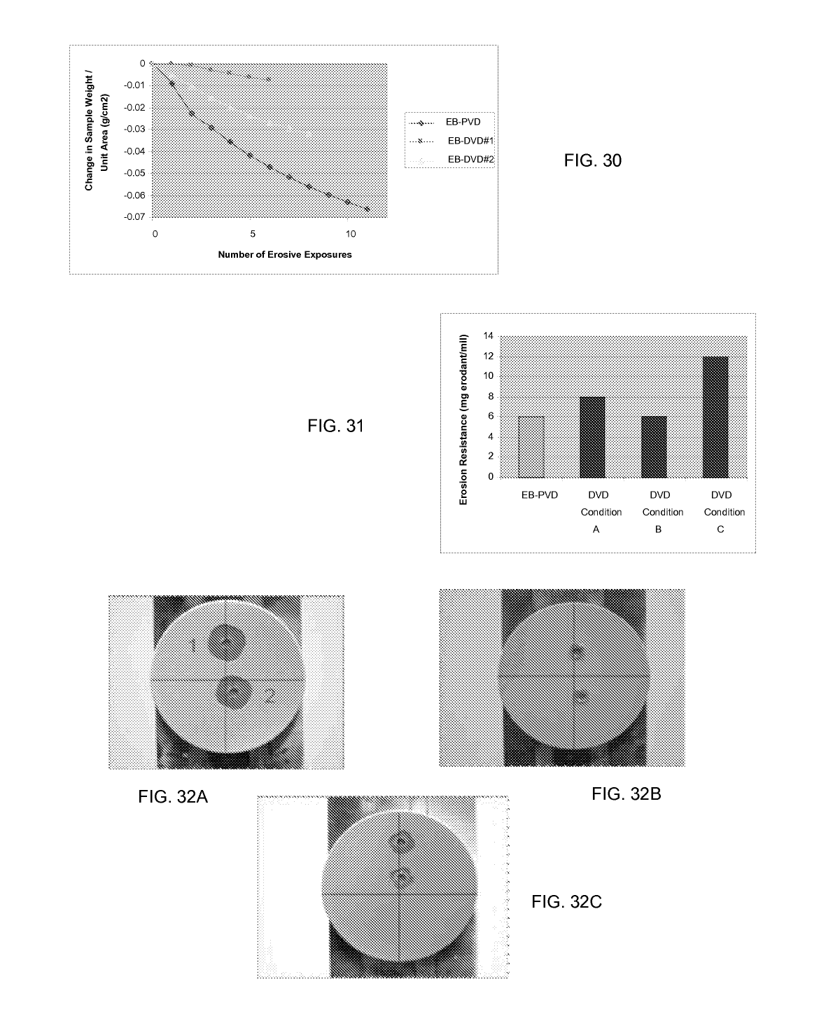

For an initial assessment of the effect of higher particle energies on DVD deposited TBC coatings, ambient temperature testing was performed on DVD deposited 7YSZ coatings using an increased particle velocity. For this testing, the Al₂O₃ media (average particle size ^{˜}70 μm) was impacted into the coating at higher pressures. For comparison purpose this testing was also performed on baseline EB-PVD 7YSZ coatings. In the case of 7YSZ coatings deposited by EB-PVD process, even after 4 impingement cycles, the coating was removed down to the substrate indicating Domain II or III type damage. DVD 7YSZ coatings showed the lower material removal rates, FIG. 30. FIG. 30 illustrates relative change of the TBC sample weight as a function of the number of 60 seconds exposures to alumina media at high nozzle pressure. The DVD deposited 7YSZ TBC coatings showed a reduced erosion rate over EB-PVD deposited 7YSZ TBC coatings.

High temperature erosion tests were also performed on 7YSZ and multi-component compositions in the temperature range of 1800-2100° F. using 27 μm size Al₂O₃ particles in a high temperature erosion rig at NASA Glenn Research Center. For this testing, the duration of heating cycle was 6 minutes followed by a 2 minute exposure to the eroding media and 6 minutes for cooling. After the erosion test, the thickness recession was measured using a Zygo optical profilometer and compared with initial thickness In FIG. 31 the variation of erosion resistance as a function of process conditions for multi-component composition is given. Note that that the same experimental trend was observed as with an ambient temperature erosion test. This suggests that the room temperature erosion test can be used as a guideline in determining the erosion performance of the coatings and that the observed improved performance is applicable at higher temperatures.

In actual engine environments, particle impingement occurs over a range of particle sizes and velocities. Thus, it is required to have coating architectures that can protect against both the erosion mechanisms of smaller impacting particles and the damage created by larger particles (i.e. impact/FOD). Therefore, tailoring the properties of the coatings to balance its effectiveness against multiple failure mechanisms is desired.

To assess the impact performance of DVD deposited TBC coatings, high temperature impact tests were performed using a burner/impact test rig at NASA Glenn Research Center. In this test, a burner torch was used to heat coupons to 2100° F. and a 1/16 inch diameter steel ball was propelled at the substrate at 400 m/s simulate an impact event. The area of coating spallation resulting from the impact was then measured and compared with standard EB-PVD deposited 7YSZ coatings to determine the relative impact resistance of the coating. The impact test results on the standard YSZ coatings are given in FIG. 31. Generally, an impact velocity of 150 m/s is adequate for TBC screening and comparison tests and the higher velocity of 400 m/s is used to determine the trend at higher energy. This data is then used as a baseline to evaluate the performance of coating architectures developed/deposited. The impact testing was performed on following coating architectures at an impact velocity of 400 m/s.

Tests were conducted on three different embodiments. A first embodiment includes a bondcoat/zirconia based topcoat, referred to as ATES-103. A first embodiment including a bondcoat/zirconia based topcoat with Ni-42Al interlayers (with three intermediate metallic layers), referred to as ATES-104. A second embodiment includes a Bondcoat/zig-zag zirconia based topcoat/Ni-42Al interlayer/multi-component (A4) outer layer, referred to as ATES-105.

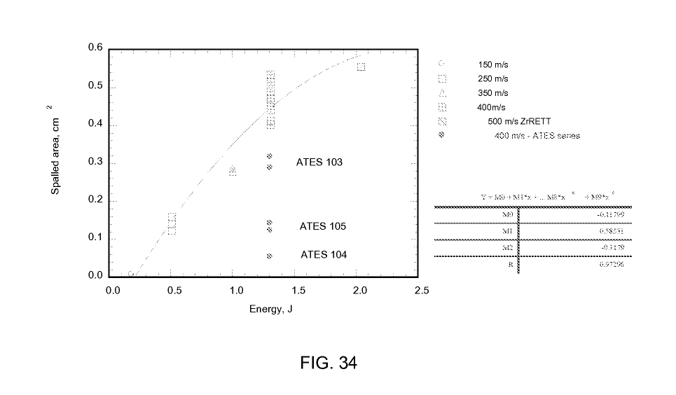

FIGS. 32A-C shows the digital images of the above mentioned samples following impact exposure. In all cases the spalled area was reduced using the DVD deposited coatings. FIG. 32A is the first embodiment for ATES-103, FIG. 32B is the second embodiment for ATES-104 and FIG. 32C is the third embodiment for ATES-105. The minimum spallation area was observed for the multilayer coating architecture FIG. 34 shows the coating spallation area in each case along with data for the baseline 7YSZ coatings. The images of FIGS. 32A-C show results after impact testing at 2011 F for an impact velocity of 400 m/s. From the data it is clear that multilayer coatings achieved excellent impact resistance at high kinetic energy (400 m/s, 1.31 J) with best performance for multilayer structure where the metallic intermediate layer absorbed the impact energy leading to a minimal coating spallation. Wherein, FIG. 33 illustrates an impact map for multi-component based TBC coatings having columnar structures (ATES-103), multilayer structures (ATES-104) and zig-zag structures (ATES-105).

Coated coupons were exposed to thermal cycling (1 hr. cycles from room temperature to 1120° C.) to assure that any modifications of the coating architecture or composition have no detrimental effect on the coating lifetime. Tests were performed using a thermal oxidation furnace for CM furnaces Inc., Bloomfield, N.J. Table 3 summarizes the lifecycle testing status for 7YSZ and multicomponent based TBC coating compositions. The use of optimized DVD process condition along with advanced TBC composition results in an increase thermal spallation resistance over baseline EB-PVD deposited TBC coatings.

TABLE 3
Summary of Thermal Spallation Testing
on DVD Deposited TBC Coatings

| | | Process | | |
|---|---|---|---|---|
| Sample | Composition | Condition | No. of cycle | Status |
| Baseline | 7YSZ | EB-PVD | 743 | Completed |
| ATES-75 | 7YSZ | DVDC | 879 | Completed |
| ATES-76 | 7YSZ | DVDC | 879 | Completed |
| ATES-75 | 7YSZ | DVDC | 1025 | Completed |
| ATES-84 | multi- | DVDB | 268 | Completed |
| | component | | | |
| ATES-68 | multi- | DVDC | 1118 | Completed |
| | component | | | |
| ATES-74 | multi- | DVDC | 1121 | Completed |
| | component | | | |
| ATES-106 | multi- | DVDC | >945 | Completed |
| | component | | | |
| ATES-107 | multi- | DVDC | >945 | Completed |
| | component | | | |

Notably, the figures and examples above are not meant to limit the scope of the present invention to a single embodiment, as other embodiments are possible by way of interchange of some or all of the described or illustrated elements. Moreover, where certain elements of the present invention can be partially or fully implemented using known components, only those portions of such known components that are necessary for an understanding of the present invention are described, and detailed descriptions of other portions of such known components are omitted so as not to obscure the invention. In the present specification, an embodiment showing a singular component should not necessarily be limited to other embodiments including a plurality of the same component, and vice-versa, unless explicitly stated otherwise herein. Moreover, Applicant does not intend for any term in the specification or claims to be ascribed an uncommon or special meaning unless explicitly set forth as such. Further, the present invention encompasses present and future known equivalents to the known components referred to herein by way of illustration.

The foregoing description of the specific embodiments so fully reveals the general nature of the invention that others can, by applying knowledge within the skill of the relevant art(s) (including the contents of the documents cited and incorporated by reference herein), readily modify and/or adapt for various applications such specific embodiments, without undue experimentation, without departing from the general concept of the present invention. Such adaptations and modifications are therefore intended to be within the meaning and range of equivalents of the disclosed embodiments, based on the teaching and guidance presented herein.

What is claimed is:

1. A process for vapor deposition onto a substrate providing impact and erosion protections for a deposition on the substrate, the process comprising:
applying a heat source to the substrate;
activating a directed vapor deposition using plasma activation to produce a high density plasma gas and vapor stream including a plurality of ions;
depositing a silicon-based bond coat on the substrate using the directed vapor deposition such that the bond coat has densified microstructures providing impact and erosion protection.

2. The process of claim 1, wherein the process is performed within a hollow-cathode plasma unit.

3. The process of claim 1 further comprising:
depositing the silicon-based bond coat in a low vacuum environment.

4. The process of claim 1 further comprising:
depositing the ions on the substrate using at least one of: self-bias of the substrate and an application of an electrical potential to the substrate.

5. The process of claim 1 further comprising:
depositing an environmental barrier coating layer on top of the silicon-based bond coat.

6. The process of claim 5 further comprising:
depositing a thermal barrier coating layer on top of the environmental barrier coating.

7. A process for vapor deposition of an environmental barrier coating (EBC) layer onto a substrate providing enhanced impact and erosion resistance for the EBC layer, the process comprising:
evaporating a source material using a thermal evaporation;
generating a high density vapor deposition stream using a gas jet source for deposition of the vapor on the substrate;
depositing the EBC layer on the substrate generating densified microstructures of the EBC layer to prove enhanced impact and erosion resistance for the EBC layer.

8. The process of claim 7, wherein the vapor deposition is electron beam physical vapor deposition.

9. The process of claim 7 further comprising:
depositing the EBC layer on a silicon based bond coat.

10. The process of claim 7 further comprising:
depositing at least one thermal barrier coating (TBC) layer on the EBC layer.

11. The process of claim 10, wherein the TBC layer includes at least one of: a zig-zag layer, a dense interlayer and a columnar layer.

12. A process for vapor deposition of a thermal barrier coating (TBC) layer onto a substrate providing enhanced impact and erosion resistance for the TBC layer, the process comprising:
evaporating a source material using a thermal evaporation;
generating a high density vapor deposition stream using a gas jet source for deposition of the vapor source on the substrate;
depositing the TBC layer on the substrate generating enhanced microstructures of the TBC layer to providing impact and erosion protection for the TBC layer.

13. The process of claim 12, the enhanced microstructures of the TBC layer include at least one of: a zig-zag layer, a dense interlayer and an outer columnar layer.

14. The process of claim 12 further comprising:
depositing the TBC layer on to a nickel super alloy.

15. The process of claim 12 further comprising:
depositing the TBC layer onto a silicon based ceramic substrate having a silicon based bond coat and an environmental barrier coating (EBC) layer applied thereon.

16. The process of claim 12 further comprising:
depositing at least one environmental barrier coating (EBC) layer on the substrate.

17. The process of claim 14 further comprising:
depositing at least one intermediate layer within the TBC layer, wherein the at least one intermediate layer is composed of at least one of: a ceramic or a metal, the intermediate layer having an enhanced density.

18. The process of claim 14, wherein an outer layer of the TBC layer has a fine columnar microstructure having a diameter of between 0.1 microns and 5 microns.

19. The process of claim 17, wherein the at least one intermediate layer exists based on at least one of: a processing variation and a composition variation, the intermediate layer having a thickness between one and fifty microns.

20. The process of claim 12, wherein the TBC layer includes an inner TBC layer and an outer TBC layer, the process further comprising:
depositing a first fine multilayer impact resistance coating containing alternating ceramic layers having the same thickness and a similar elastic modulus, the layer thickness being between 0.1 microns and 5 microns;
depositing a columnar top coat coating upon the first fine multilayer impact resistance coating;
depositing the inner TBC layer on the columnar top coat, the inner TBC layer comprises a columnar layer;
depositing a second fine multilayer on the inner TBC layer; and
depositing the outer TBC layer on the second finer multilayer, the outer TBC layer comprises a columnar layer.

21. A process for directed vapor depositions and application of a plurality of protective coatings providing enhanced impact and erosion resistance for the coatings, the process comprising:
depositing a silicon based bond coat using plasma activation on a substrate;
depositing an environmental barrier coating on the silicon based bond coat as an inner layer using a first gas jet source for deposition;
depositing a thermal barrier coating as an outer layer using a second gas jet source for deposition;
depositing at least one intermediate layer disposed between the inner layer and the outer layer using the directed vapor deposition, the intermediate layer include one or more of: a fine multilayer, a columnar layer, a zig-zag layer, an enhanced density metal layer, an enhanced density ceramic layer, and a columnar thermal barrier coating layer.
